(19) United States
(12) Patent Application Publication
(10) Pub. No.: US 2012/0126119 A1
(43) Pub. Date: May 24, 2012

(54) Charged-Particle-Beam Device

(75) Inventors: Ritsuo Fukaya, Hitachinaka (JP); Kazuhiro Ueda, Hitachinaka (JP)

(73) Assignee: Hitachi High-Technologies Corporation, Minato-ku, Tokyo (JP)

(21) Appl. No.: 13/387,256

(22) PCT Filed: Jul. 27, 2010
(86) PCT No.: PCT/JP2010/062586

§ 371 Date: Jan. 26, 2012

(30) Foreign Application Priority Data
Jul. 27, 2009 (JP) 2009-174542

(51) Int. Cl. H01J 37/28

(52) U.S. Cl. 250/310

(57) ABSTRACT

To automatically measure patterns arranged symmetrically with respect to the axis of rotation on a sample by following predetermined procedures, a charged-particle-beam device of the present invention automatically rotates a template image to be used for template matching by an angle (θ1) calculated from the coordinates on the sample. Accordingly, when patterns arranged regularly and symmetrically with respect to the axis of rotation are automatically measured, the same template can be repeatedly used as in a case where devices arranged iteratively in a lattice-like fashion are observed or measured. Thus, the workload required to create a recipe can be reduced.

### TECHNICAL FIELD

The present invention relates to a charged-particle-beam device that observes or measures fine pattern forms arranged on a sample surface symmetrically with respect to the axis of rotation. The present invention is applied to a scanning electron microscope that observes or measures fine patterns formed on a disk (a platter) having a recording surface, and the patterns of a nanoimprint mask to serve as the transfer matrix for forming the fine patterns in a process to manufacture a magnetic recording hard disk, for example. It should be noted that “charged particles” include ions as well as electrons.

### BACKGROUND ART

In a process to manufacture a semiconductor device by a microfabrication technique such as LSI, a special-purpose scanning electron microscope called a “length measuring SEM (Scanning Electron Microscope)” is used to determine whether fine pattern shapes formed in respective procedures are within a desired dimension range. A length measuring SEM is formed by combining a low-acceleration SEM having a short-focus objective lens with a sample moving mechanism that transports a silicon wafer on which semiconductor devices are to be formed and aligns a desired location on the wafer with the optical axis of the electron microscope. Such a length measuring SEM processes each acquired observation image with special-purpose software, and calculates the dimensions of a desired portion in the image.

At present, the technology used in the manufacture of semiconductor devices is called photolithography. A pattern drawn on a plate made of quartz or the like is exposed and projected onto a photosensitive material applied onto a silicon wafer with a short-wavelength ultraviolet ray or an X-ray, and the pattern is transferred by taking advantage of the chemical reaction caused by the energy of the projection light. Normally, several tens to several hundreds of devices that are the same are formed on a single wafer. Therefore, rectangular devices are arranged in a lattice-like fashion, and an exposure is repetitively performed. In view of this, the coordinate system for managing locations on the wafer is normally an X-Y biaxial orthogonal coordinate system (a Cartesian coordinate system), and the sample moving mechanism is normally a mechanism formed by combining two uniaxial straight movement mechanisms. As described above, a large number of devices are to be formed on a single wafer, and therefore, measurement of the dimensions of each device is automatically carried out by following predetermined procedures. The following is an example of the procedures for the automatic measurement.

1) A notch located on the outer circumference is detected while the wafer is rotated, and the orientation of the wafer is aligned with the notch.

2) The wafer is carried into a vacuum chamber, and the vacuum chamber is evacuated.

3) “Alignment marks” formed at predetermined locations on the wafer are detected, and a coordinate system on the wafer is set.

4) The wafer is moved by a sample moving mechanism, so that the optical axis (or the observation area) of the electronic optical system is aligned with the coordinates of a preset measurement point.

5) A SEM image at a point in the vicinity of the measurement point is acquired, and is compared with a “template” stored beforehand in the device. As the template, a pattern that is easily referred to and has a shape unlike any of other patterns in the surrounding area is selected. A reference object pattern and the information about the relative distance from the patterns to be measured are stored in the template. The reference object pattern in the SEM image is identified, so that the location of the measurement object pattern can be accurately calculated. This is to correct the coordinate errors due to the mechanical inaccuracy of the sample moving mechanism. In this specification, this operation will be hereinafter referred to as “addressing.”

6) The optical axis is moved to the measurement point. At this point, the optical axis is displaced with the use of the functions of the electronic optical system. The moving of the optical axis with the electronic optical system enables positioning with much higher precision than positioning performed by mechanically moving the optical axis.

7) The SEM image at the measurement point is acquired, and a desired dimension is measured. The desired measurement portion in the image is detected by referring to another “template” image.

8) The above procedures (4) through (7) are repeated.

9) After all the desired measurement points are measured, the wafer is moved out of the vacuum chamber.

The above series of procedures are set in electronic data called a “recipe,” including the locations of the measurement points, the template images, and the like.

In the above described automatic length measurement, templates are required in the two stages of addressing and length measurement. In a conventional semiconductor wafer, devices are unidirectionally arranged in a lattice-like fashion on the wafer, and the respective devices have the same interconnect patterns. Therefore, the respective devices are in a translationally symmetric relationship with one another, and the same template can be used for the device at any location in the lattice arrangement. That is, the shape of a desired portion in a device in the arrangement is stored in the device, and is used as the template. In this manner, the same template can be used without any specific operations in the measurement of the device at any other location in the lattice arrangement. This is an important point in facilitating the creation of the “recipe” that defines the measurement procedures for measurement automation.

In recent years, the following technique has been used. To increase recoding density in magnetic hard disks for storing data, minute dot-like convex portions are formed in the surface of each disk (called a platter) that is conventionally flat. These convex portions are made to correspond to recording bits, so that interference from adjacent bits is prevented, and the bit intervals are made shorter. As the dots need to be arranged circumferentially on the platter, circumferential grooves or concave rows are formed beforehand in the platter surface, and the dots are formed in the grooves or concave rows. The formation of the grooves is performed by using a so-called “nanoimprint” process. This process is to form fine patterns not by light projection but by pressing a mold directly against a molding material (see Non-Patent Literatures 1 and 2).

### CITATION LIST

### Non-Patent Literature

Non-Patent Literature 1: 2007 Nanoimprint Technology Outlook, pp. 150-154, Electronic Journal, Inc., 2007
Non-Patent Literature 2: Same as above, pp. 159-162

### SUMMARY OF INVENTION

### Technical Problem

In the above described nanoimprint process for magnetic hard disks, the dimensions of the grooves or concave rows that define the dot arrangement affect the performance of each hard disk device. Therefore, it is necessary to examine the dimensions of the mold to serve as the matrix for nanoimprint. The mold is normally formed by forming patterns on a disk-like quartz wafer. In a quartz wafer for molding, as in a silicon wafer, a small notch for uniquely defining the orientation of the substrate is normally formed at a location on the outer circumference. The dimensions of the patterns formed in the surface are several tens of nanometers, and a dimensional inspection with a SEM is useful.

When the above described mold is inspected with a conventional length measuring SEM, however, the following problem occurs. Specifically, the patterns on the mold wafer are arranged not in a lattice-like fashion but in a symmetrical manner with respect to the axis of rotation. FIG. 3 shows an example of the arrangement of patterns formed in the mold. The patterns are arranged on a circumference in the wafer, and the angles of the patterns vary with locations on the circumference. Therefore, even if one template is prepared for identical patterns as in a case where devices arranged in a lattice-like fashion are automatically measured, the mold cannot be automatically measured. As a result, in a case where multiple similar patterns located on the same circumference are measured, templates with different angles that vary with measurement sites need to be prepared even for patterns having measurement objects with congruent shapes. This leads to a large increase in the workload required for creating the automatic measurement recipe.

### Solution to Problem

The present invention provides a technique for acquiring an image by automatically rotating a template image, or rotating an image at an observation point or a measurement point, or automatically rotating the visual field area serving as the scanning range of a charged-particle beam, by an angle calculated from the coordinates on a sample when the shapes of the patterns arranged symmetrically with respect to the axis of rotation on the sample are automatically observed or measured by following predetermined procedures.

### Advantageous Effects of Invention

According to the present invention, the number of templates to be registered as a recipe beforehand into a charged-particle-beam device can be reduced. Accordingly, the workload required for creating the recipe can be reduced.

### BRIEF DESCRIPTION OF DRAWINGS

FIG. 1 is a diagram for explaining the structure of a scanning electron microscope that is an embodiment of the present invention.

FIG. 2 is diagrams for explaining the control output waveforms observed when the scanning electron microscope scans a sample surface with an electron beam.

FIG. 3 is a diagram for explaining a sample measuring method according to the present invention.

### DESCRIPTION OF EMBODIMENTS

The following is a description of embodiments of the present invention, with reference to the drawings. The device structure and the contents of the processing operation described in the following are mere examples, and other embodiments can be realized by combining the embodiments with a known technique or replacing some aspects of the embodiments with a known technique.

### (A) Fundamental Principles

In the embodiments described below, an appropriate angle of a template is calculated through a calculation using the location coordinates of a measurement point on a mold, and the process to create an automatic measurement recipe can be made easier.

Normally, patterns formed on the same circumference in a mold surface regulate recording bits and are regularly arranged. Therefore, even if the patterns are located at various locations on the circumference, those patterns can be regarded as identical when rotated as needed. Accordingly, by using an angle θ obtained by the following calculation, for example, a mutual conversion can be performed between the rotation angle θ and the coordinate values in the Cartesian coordinate system.

[Mathematical Formula 1]

θ(x,y)=tan⁻¹(x/y) (i)

x, y: the coordinates of a measurement point in the Cartesian coordinate system, with the wafer center point being the origin

The notch being in the positive y-direction

θ: the rotation angle of each pattern with respect to the pattern located on the radius extending through the notch

The mathematical formula (i) changes its form with the coordinate system. In any case, the rotation angle θ (0≦θ<360 degrees) can be uniquely obtained from the coordinates (x, y). In this specification, the rotation angle θ is an angle with respect to a reference position clockwise. However, the rotation angle θ can be expressed as a rotation angle θ (0≦θ<180 degrees) with respect to the reference position clockwise, and a rotation angle θ (−180 degrees≦θ<0) with respect to the reference position counterclockwise.

When an automatic measurement recipe is created, the template (A) at the measurement point corresponding to the rotation angle θ of 0 is stored, for example. The template (B) for a measurement point on the same circumference can be readily acquired by rotating the template (A) by the rotation angle θ calculated by the mathematical formula (i). In view of this, according to the present invention, the process to create the automatic measurement recipe in repeatedly measuring identical patterns located on the same circumference can be dramatically simplified by applying the rotation angle θ to the template of each measurement point.

The same effect as above can be realized without rotation of a template. That is, while a template is fixed, the scanning area of the charged-particle beam (or the image to be acquired) is rotated by the rotation angle θ, so as to realize the same positional relationship as above. To rotate an acquired image, the direction of an SEM scanning the sample surface with an electron beam needs to be rotated. However, the rotation of the scanning direction is a widely-used technique.

The coordinate system on a wafer surface can be a polar coordinate system that is designated by a moving radius and an angle. However, the precise positioning device for aligning each measurement point on a wafer with the optical axis of the electronic optical system of the SEM is normally of a biaxial orthogonal type. Therefore, the coordinate transformation process inside the device accompanying the positioning becomes complicated. Therefore, the present invention is preferable.

### (B) Embodiment 1

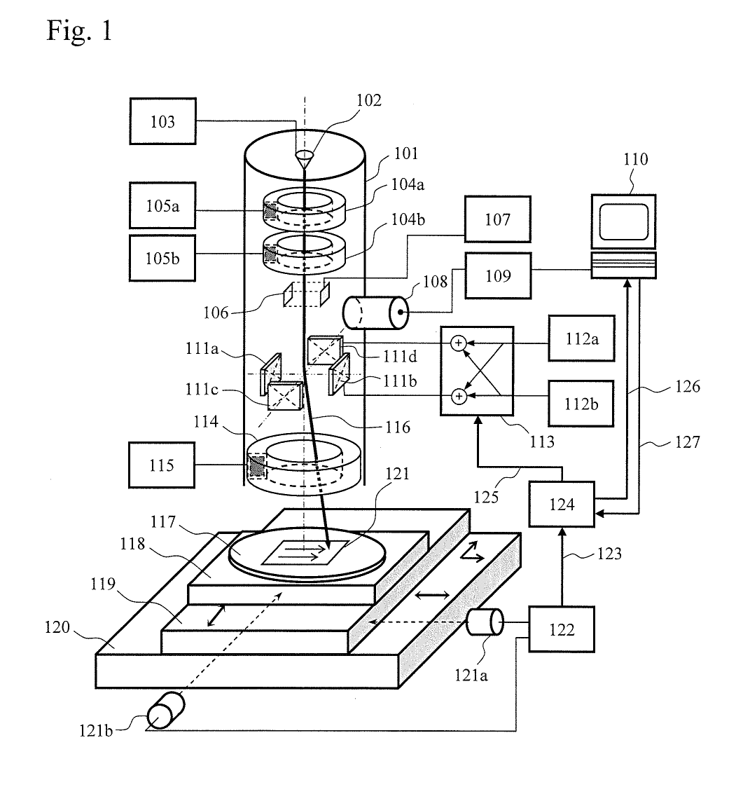

FIG. 1 is a schematic view of the structure of a scanning electron microscope according to an embodiment of the present invention.

An electron source 102 is located at an upper portion of a lens tube 101 of an electronic optical system that maintains high vacuum therein. A high voltage of several kilovolts is applied to the electron source 102 from an electron source power supply 103. Through the high voltage application, a primary electron beam 116 is supplied. The primary electron beam 116 is focused, as needed, by two condenser lenses 104a and 104b that are controlled by power supplies 105a and 105b, respectively.

The primary electron beam 116 passes through deflectors 111a, 111b, 111c, and 111d that deflect the traveling direction of an electron beam, and lastly, is focused onto the surface of a sample 117 by an objective lens 114 that is controlled by a power supply 115. Secondary electrons are generated from the convergence point of the primary electron beam 116. The secondary electrons move upward in the lens tube, and enter a detector 108. After converted into an electrical signal, the secondary electrons form an image that reflects the shape of the sample surface on a main control device 110 via an amplifier 109. To avoid complication, the secondary electrons are not shown in the drawing.

The sample 117 is placed on an X-Y stage that includes a Y-table 118 and an X-table 119 that are also located under high vacuum. The X-table 119 has the mechanism to move in the X-direction (the horizontal direction in the drawing) on a base 120. The Y-table 118 has the mechanism to move in the Y-direction (the depth direction in the drawing) on the X-table 119. The locations of the X-table 119 and the Y-table 118 are measured by location detectors 121a and 121b, respectively. The measurement results are converted into an electrical signal 123 indicating location information by a converter 122.

The location detectors are normally optical interferometric perimeters that sense phase shifting of the reflected light obtained by emitting a laser beam onto a table. With the above mentioned two tables and location detectors, the location of the sample 117 relative to the lens tube 101 can be detected or controlled to an accuracy of several micrometers. Deflection power supplies 112a and 112b are connected to the above described deflectors via a signal mixer 113.

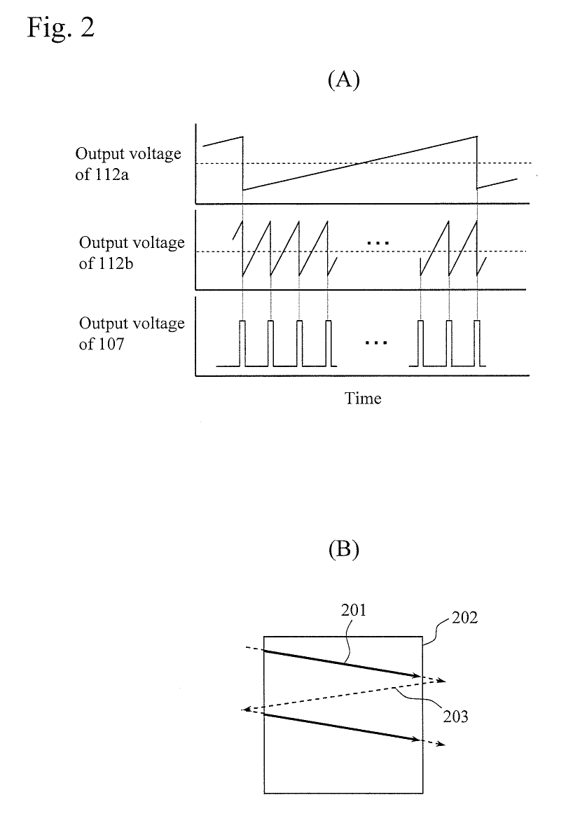

In the scanning electron microscope, the primary objective of those deflectors is to perform scanning in a flat-face area 121 on the sample surface with an electron beam. In this embodiment, four-pole electrostatic deflectors that deflect an electron beam in two directions perpendicular to each other are described. There are other types of deflectors such as eight-pole electrostatic deflectors and bidirectional electromagnetic deflectors, but the use of any type does not affect the essence of the invention. The respective voltages shown in FIG. 2(A) are applied to the two pairs of deflectors perpendicular to each other.

A short-cycle sawtooth voltage is applied to the deflection power supply 112b, for example. At the tilted portions of the sawtooth voltage, the primary electron beam is displaced in the transverse direction of the visual field area 202 shown in FIG. 2(B). A long-cycle sawtooth voltage with an integral multiple (normally about 1000) of the cycles of the voltage applied to the deflection power supply 112b is applied to the deflection power supply 112a, for example. At the tilted portions of the sawtooth voltage, the primary electron beam is displaced in the longitudinal direction of the visual field area 202 shown in FIG. 2(B).

At those sawtooth voltages, the primary electron beam successively performs scanning in the area 121 (202) on the sample 117. This is a general technique for scanning a flat face with a charged-particle beam. The unnecessary trajectory 127 (the trajectory 203 indicated by a dashed line in FIG. 2(B)) of the primary electron beam displaced by the sawtooth voltage is cut off by applying the pulse voltage shown in FIG. 2(A) from a power supply 107 to a breaker 106 provided at an upper portion of the lens tube. As a result, only an effective trajectory 126 in the desired area (the trajectory 201 indicated by the solid lines in FIG. 2(B)) is used for scanning.

The signal mixer 113 is located between the deflection power supplies 112a and 112b, and the deflectors 111a, 111b, 111c, and 111d. The signal mixer 113 can mix the sawtooth voltages supplied from the deflection power supplies 112a and 112b at a preset ratio, and output the voltages to each of the deflectors. At this point, the deflection area or the scanning area (corresponding to the visual field area in the claims) of the primary electron beam 116 rotates on the sample surface, depending on the mixture ratio in accordance with the preset ratio. That is, the acquired image displayed on the main control device 110 can be arbitrarily rotated by changing the mixture ratio. It goes without saying that only the visual field area rotates, and the external shape does not change.

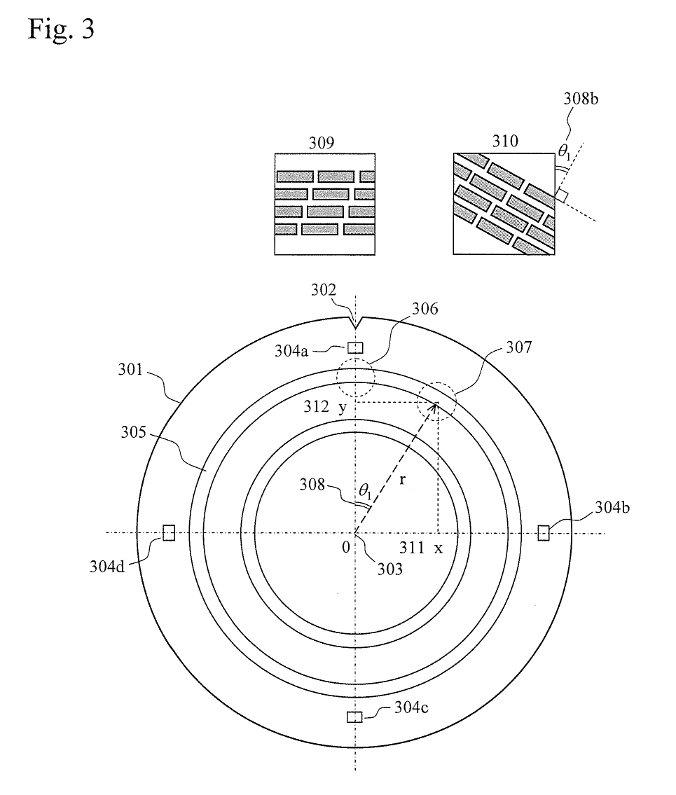

Referring now to FIG. 3, an operation according to the embodiment is described. FIG. 3 is a schematic view of a nanoimprint mold for performing fine processing on a magnetic-recording hard-disk platter to which the embodiment is to be applied. A notch 302 indicating the origin of angle is formed in a disk-like wafer 301 made of quartz. The radius extending from the wafer center 303 to the notch is set as the reference line.

Several (four in FIG. 3) alignment marks 304a, 304b, 304c, and 304d are located in predetermined positions with respect to the reference line in the wafer 301. The alignment marks are designed for correcting the coordinate system of biaxial orthogonal tables 118 and 119 in the device, and the device design coordinate system that is set on the wafer.

When the wafer 301 is carried into a length measuring SEM, at least two alignment marks are first detected. The planned coordinates of the alignment marks are known. Therefore, the mechanical errors of the locking mechanism of the wafer 301, and the mechanical errors of the Y-table 118 and the X-table 119 can be corrected. After that, the wafer 301 is moved to a desired measurement point, and the image acquired by the scanning with the primary electron beam 116 is compared with a template that is set beforehand in an automatic measurement recipe. The length measurement SEM detects and measures the measurement point that matches that of the template.

The following is a description of a case where a point 307 at an angle θ₁ (308) away from a measurement point 306 and a reference point located on the notch reference line is to be measured on a circumference 305. The pattern on the circumference has regular arrangement with symmetry with respect to the axis of rotation.

If the length measurement pattern at the measurement point 306 is the pattern shown in an image 309, the length measurement pattern at the measurement point 307 is the pattern shown in an image 310. As can be easily seen from a comparison between the image 309 and the image 310, the sequence pattern in the image 310 is formed by rotating the sequence pattern in the image 309 by an angle θ₁ (308b).

By a conventional technique, different templates are required for the measurement point 306 and the measurement point 307 in such a case. That is, template images independent of each other need to be acquired for the measurement point 306 and the measurement point 307.

In this embodiment, on the other hand, the image 309 to serve as a template is acquired at the measurement point 306. At the measurement point 307, the acquired image 309 as a template is rotated by the angle θ₁, so that a template equivalent to the image 310 is acquired. Since the scanning electron microscope has the values of coordinates 311 and 312, the angle θ₁ can be calculated by plugging the x-coordinate 311 and the y-coordinate 312 on the wafer at the measurement point 307 into the above mentioned mathematical formula (i).

It should be noted that the image used as the template in a rotated state may be recorded at each measurement point in the recipe at the time of creation of the recipe, or may be generated at each measurement point after each time the wafer is rotated when the recipe is executed. Either case can be realized where the electrical signal 123 obtained from the table coordinates detected by the location detectors 121a and 121b in FIG. 1 is converted into a rotation angle by the location-rotation angle calculating device 124, and the result 126 is sent to the main control device 110.

Although the image of the template is rotated in accordance with the location of an image to be acquired in the above description, conversely, the image of the template may be fixed, and each acquired image may be rotated by a rotation angle with respect to the location of the template through image processing.

### (C) Embodiment 2

Next, a schematic view of the structure of a scanning electron microscope according to Embodiment 2 is shown. It should be noted that the fundamental structure is the same as the structure of the scanning electron microscope illustrated in FIG. 1. In the following, only the differences from Embodiment 1 are described.

In Embodiment 1, the image of the template is rotated by an optimum rotation angle θ in accordance with each measurement point. In Embodiment 2, on the other hand, the image of the template is fixed (that is, the image of the template is not rotated), and the acquirement range (the visual field area) in which an image acquired at the time of measurement is rotated.

The measurement point 306 is also set as the location to acquire the template image 309. In this embodiment, the visual field area is rotated by the rotation angle −θ₁ (308) when the image of the measurement point 307 is acquired.

Like the image 310, the image acquired at the measurement point 307 has a tilted sequence pattern in the visual field area. The sequence pattern is rotated by a rotation angle −θ₁, so that an image equivalent to the image 309 corresponding to the template can be readily acquired.

The rotation angle −θ₁ is calculated by the location-rotation angle calculating device 124, based on the electrical signal 123, and the signal mixer 113 is controlled based on a control signal 125. In this manner, a rotated image can be readily acquired. Instead of the electrical signal 123, coordinate value data 127 that is recorded in the recipe may be sent to the location-rotation angle calculating device 124, to control the rotation angle.

### (D) Advantages of the Embodiments

As described above, by using either technique according to the embodiments, it is possible to reduce the number of image templates to be used by the automatic measurement recipe when the fine dimensions of repetitive pattern shapes arranged on a wafer symmetrically with respect to the axis of rotation are measured. Either technique is particularly effective in a case where a wafer that has the same patterns regularly arranged on the same circumference, like a magnetic recording hard disk, is measured.

### (E) Other Embodiments

Although an embodiment of the present invention has been described, arranging patterns symmetrically with respect to the axis of rotation is critically important in the mold wafer illustrated in FIG. 3, and those embodiments are not necessarily effective only at two points located on the same circumference. Therefore, it goes without saying that objects for which the present invention is effective include different structures from that illustrated in the schematic view shown in FIG. 3.

Also, as long as the patterns to be measured are arranged symmetrically with respect to the axis of rotation, the present invention can be applied not only to the above described nanoimprint molds for magnetic recording hard disks, but also to optical recording disks, optical elements, and others.

### INDUSTRIAL APPLICABILITY

In a process to observe/examine a sample such as a magnetic recording hard disk having fine patterns arranged symmetrically with respect to the axis of rotation on the sample surface to be observed with a scanning electron microscope using charged particles, the period of time to be spent to create the recipe defining the automatic measurement procedures can be reduced, and inexpensive highly-efficient equipments can be manufactured.

### REFERENCE SIGNS LIST

101 lens tube
102 electron source
103 electron source power supply
104a, 104b condenser lenses
105a, 105b power supplies
106 breaker
107 power supply
108 detector
109 amplifier
110 main control device
111a, 111b, 111c, 111d deflectors
112a, 112b deflection power supplies
113 signal mixer
114 objective lens
115 power supply
116 primary electron beam
117 sample
118 Y-table
119 X-table
120 base
121a, 121b location detectors
122 converter
123 location information electrical signal
124 location-rotation angle calculating device
125 control signal
126 rotation angle data
127 coordinate value data

1. A charged-particle-beam device that scans a surface of a sample with a focused charged-particle beam, captures and detects generated secondary electrons or reflected electrons, and converts the electrons into a luminance signal to form an image,
wherein, to automatically observe or measure patterns arranged symmetrically with respect to an axis of rotation on the sample by following predetermined procedures, the charged-particle-beam device automatically rotates a template image or an image at an observation point or a measurement point by an optimum angle, based on a relationship between a coordinate location of the template image for location detection on the sample and a coordinate location of the observation point or the measurement point on the sample.

2. The charged-particle-beam device according to claim 1, wherein a stage on which the sample is mounted is driven by an X-Y drive system.

3. A charged-particle-beam device that scans a surface of a sample with a focused charged-particle beam, captures and detects generated secondary electrons or reflected electrons, and converts the electrons into a luminance signal to form an image,
wherein, to automatically observe or measure patterns arranged symmetrically with respect to an axis of rotation on the sample by following predetermined procedures, the charged-particle-beam device acquires an image by automatically rotating a visual field area by an optimum angle, based on coordinates of an observation point or a measurement point on a wafer, the visual field area being a scanning range of the charged-particle beam.

4. The charged-particle-beam device according to claim 3, wherein a stage on which the sample is mounted is driven by an X-Y drive system.
